(19) United States
(12) Patent Application Publication
(10) Pub. No.: US 2008/0224703 A1
(43) Pub. Date: Sep. 18, 2008

(54) Method and device for magnetic resonance analysis

(75) Inventors: Gregory Molev, Haifa (IL); Dmitry Bravo-Zhivotovskii, Nesher (IL)

Correspondence Address: Martin D. Moynihan;PRTSI, Inc., P.O. Box 16446, Arlington, VA, 22215, US

(73) Assignee: Technion Research & Development Foundation Ltd., Haifa (IL)

(21) Appl. No.: 12/073,993

(22) Filed: Mar. 12, 2008

Related U.S. Application Data
(60) Provisional application No. 60/906,181, filed on Mar. 12, 2007.

(51) Int. Cl. G01R 33/30; B29C 65/00

(52) U.S. Cl. 324/321; 156/285

(57) ABSTRACT

A device for NMR spectroscopy is disclosed. The device comprises a sealed capillary having therein a lock material.

### RELATED APPLICATIONS

This application claims the benefit of U.S. Provisional Patent Application No. 60/906,181 filed on Mar. 12, 2007, the contents of which are hereby incorporated by reference.

### FIELD AND BACKGROUND OF THE INVENTION

The present invention, in some embodiments thereof, relates to spectroscopy and, more particularly, but not exclusively, to a method and device for magnetic resonance analysis.

Spectroscopy generally refers to the study of chemical and physical microscopic properties of a substance by observation of its interaction with electromagnetic radiation. One type of spectroscopy utilizes a quantum mechanical phenomenon, named Nuclear Magnetic Resonance (NMR), in which a system of spins, placed in a magnetic field resonantly absorbs energy when applied with a certain frequency. NMR spectroscopy allows analysis of molecular scaffolds on the atomic level in a non-destructive way.

A nucleus can experience NMR only if its nuclear spin I does not vanish, i.e., the nucleus has at least one unpaired nucleon. Examples of non-zero spin nuclei include ¹H (I=½), ²H (I=1), ²³Na (I= 3/2), etc. When placed in a magnetic field, a nucleus having a spin I is allowed to be in a discrete set of energy levels, the number of which is determined by I, and the separation of which is determined by the gyromagnetic ratio of the nucleus and by the magnetic field. Under the influence of a small perturbation, manifested as a radiofrequency magnetic field rotating about the direction of a primary static magnetic field, the nucleus has a time dependent probability to experience a transition from one energy level to another. With a specific frequency of the rotating magnetic field, the transition probability may reach the value of unity. Hence at certain times, a transition is forced on the nucleus, even though the rotating magnetic field may be of small magnitude relative to the primary magnetic field. For an ensemble of spin I nuclei the transitions are realized through a change in the overall magnetization.

Once a change in the magnetization occurs, a system of spins tends to restore its magnetization longitudinal equilibrium value, by the thermodynamic principle of minimal energy. The time constant which control the elapsed time for the system to return to the equilibrium value is called “spin-lattice relaxation time” or “longitudinal relaxation time” and is denoted T₁. An additional time constant, T₂ (≦T₁), called “spin-spin relaxation time” or “transverse relaxation time”, controls the elapsed time in which the transverse magnetization diminishes, by the principle of maximal entropy. However, inter-molecule interactions and local variations in the value of the static magnetic field, alter the value of T₂, to an actual value denoted T₂*.

The resonance frequency of a particular nucleus depends on the strength of the magnetic field at the nucleus. To allow comparison of results obtained using NMR spectrometers operating at different field strengths, NMR spectra are typically analyzed by means of chemical shifts. The chemical shift of a nucleus is defined as the difference between the resonance frequency of the nucleus and the resonance frequency of a reference nucleus relative to the resonance frequency of the reference nucleus. The chemical shift is typically measured in parts per million (ppm), hence given by δ=10⁶(ν−ν_{ref})/ν_{ref}, where δ, ν and ν_{ref} are the chemical shift, the resonance frequency of the nucleus and the resonance frequency of the reference nucleus, respectively.

The electron density around each nucleus in a molecule varies according to the types of nuclei and bonds in the molecule. Since the electrons partially shield the magnetic field, the effective field at each nucleus is shifted (generally less) with respect to the applied magnetic field. The chemical shift is therefore a precise metric of the electronic environment in the molecule.

In NMR spectroscopy the sample typically includes a solute and a deuterated solvent that contains deuterium in place of hydrogen. The NMR signal from the deuterium nuclei is oftentimes referred to as the “NMR Lock,” and NMR spectrometers are equipped with a lock mechanism which facilitates centering the deuterium signal on a predefined lock frequency. Once the lock mechanism is engaged, the NMR spectrometer continuously monitors the signal from the deuterated solvent and compensates for any drifting of the magnetic field hence prevents peak broadening. In many NMR spectroscopy techniques, the deuterated solvent also serves as a chemical shift reference for the analysis of the solute.

Known in the art are devices for NMR spectroscopy manufactured as two coaxial tubes in which an inner tube, also known as an insert, is accurately centered with respect to an outer tube (to this end see, e.g., István Pelczer and Frank Bosco, http://www.niehs.nih.gov/dert/metabol.htm, downloaded on Feb. 12, 2007 and Wilmad-Labglass publications “NMR-007: Coaxial Inserts in NMR Studies,” http://www.wilmad-labglass.com/services/NMR_{—}007.jsp and “Stem Coaxial Inserts,” http://www.wilmad-labglass.com/group/2093, downloaded on Mar. 9, 2008). In such devices the sample to be analyzed is separated from the lock or reference material, whereby one substance is placed in the outer tube and the other is placed in the inner tube.

### SUMMARY OF THE INVENTION

According to an aspect of some embodiments of the present invention there is provided a device for NMR spectroscopy. The device comprises a sealed capillary having therein a lock material. In various exemplary embodiments of the invention the capillary is positionable within an NMR sample tube in a non-coaxial manner.

According to an aspect of some embodiments of the present invention there is provided an NMR kit. The kit comprises one NMR or more sample tubes, and one or more sealed capillary having therein a lock material and being positionable within the NMR sample tube in a non-coaxial manner.

According to an aspect of some embodiments of the present invention there is provided a method of analyzing a sample, comprising: placing the sample in an NMR sample tube; placing a sealed capillary having therein a lock material in the NMR sample tube in a non-coaxial manner; and performing an NMR spectroscopy. In various exemplary embodiments of the invention the sample is a non-deuterated sample.

According to some embodiments of the present invention the capillary is flame-sealed.

According to an aspect of some embodiments of the present invention there is provided a method of manufacturing a device for NMR spectroscopy, comprising filling a capillary with a lock material, and sealing the capillary while ensuring vacuum conditions in the capillary.

According to some embodiments of the present invention the sealing is by a sealing flame.

According to some embodiments of the present invention the lock material comprises a deuterated solvent.

According to some embodiments of the invention the deuterated solvent comprises deuterobenzene (C₆D₆).

According to some embodiments of the invention the deuterated solvent comprises deuterotoluene (C₇D₈).

According to some embodiments of the invention the deuterated solvent comprises deuteromethanol. According to some embodiments of the invention the deuteromethanol is CH₃OD. According to some embodiments of the invention the deuteromethanol is CD₃OD.

According to some embodiments of the invention the deuterated solvent comprises deuteroacetone ((CD₃)₂CO).

According to some embodiments of the invention the deuterated solvent comprises acetonitryl-d (CD₃CN).

According to some embodiments of the invention the deuterated solvent comprises tetrahydrofurane-d. According to some embodiments of the present invention the tetrahydrofurane-d is THF-D₄. According to some embodiments of the present invention the tetrahydrofurane-d is THF-D₈.

According to some embodiments of the invention the deuterated solvent comprises deuterochloroform (CDCl₃).

According to some embodiments of the invention the deuterated solvent comprises methylenechloride-d (CD₂Cl₃).

According to some embodiments of the invention the deuterated solvent comprises deuterodimethylsulfoxide (DMSO-d₆).

According to some embodiments of the invention the deuterated solvent comprises dimetylformamide-d. According to some embodiments of the present invention the dimetylformamide-d is (CD₃)₂NCDO. According to some embodiments of the present invention the dimetylformamide-d is (CD₃)₂NCHO.

According to some embodiments of the invention the deuterated solvent comprises deuteriumoxide (D₂O).

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

### BRIEF DESCRIPTION OF THE DRAWINGS

Some embodiments of the invention are herein described, by way of example only, with reference to the accompanying drawings and/or images. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIGS. 1a-b are schematic illustrations of conventional NMR spectroscopy procedures;

FIGS. 2a-c are schematic illustrations of a device for NMR spectroscopy, according to various exemplary embodiments of the present invention;

FIGS. 3a-b are images showing a prototype of device for NMR spectroscopy, according to various exemplary embodiments of the present invention;

FIGS. 4-6 are schematic illustrations of a method of analyzing a non-deuterated sample, according to various exemplary embodiments of the present invention;

FIG. 7a is an ¹H NMR spectrum of D-galactose peracetate in CDCl₃ as acquired using traditional technique;

FIGS. 7b is an ¹H NMR spectrum of D-galactose peracetate in CHCl₃ as acquired using a capillary having therein DMSO-d₆ in accordance with some embodiments of the present invention;

FIG. 8a is a ¹³C NMR spectrum of D-galactose peracetate in CDCl₃ as acquired using traditional technique; and

FIG. 8b is a ¹³C NMR spectrum of D-galactose peracetate in CHCl₃ as acquired using a capillary having therein DMSO-d₆ in accordance with some embodiments of the present invention; and

FIG. 9a is a ¹H NMR spectrum of t-BuMe₂SiH C₆D₆ as acquired using traditional technique;

FIG. 9b is a ¹³C NMR spectrum of t-BuMe₂SiH C₆H₆ as acquired using a capillary having therein DMSO-d₆ in accordance with some embodiments of the present invention; and

FIGS. 10a-d are schematic illustration of a method suitable for manufacturing a device for NMR spectroscopy according to various exemplary embodiments of the present invention.

### DESCRIPTION OF SPECIFIC EMBODIMENTS OF THE INVENTION

The present invention, in some embodiments thereof, relates to spectroscopy and, more particularly, but not exclusively, to a method and device for magnetic resonance analysis.

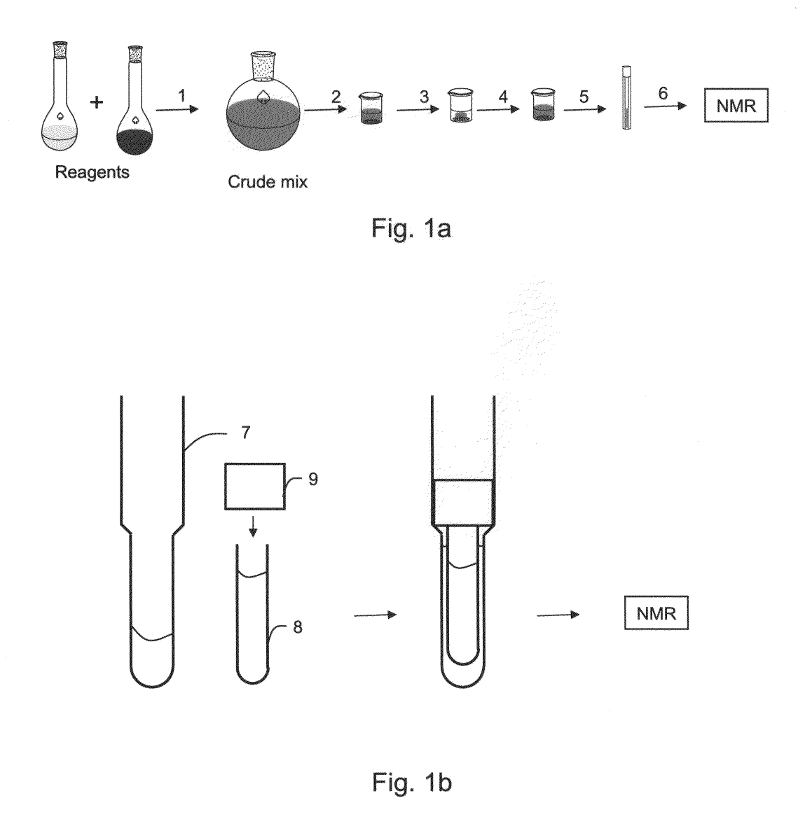

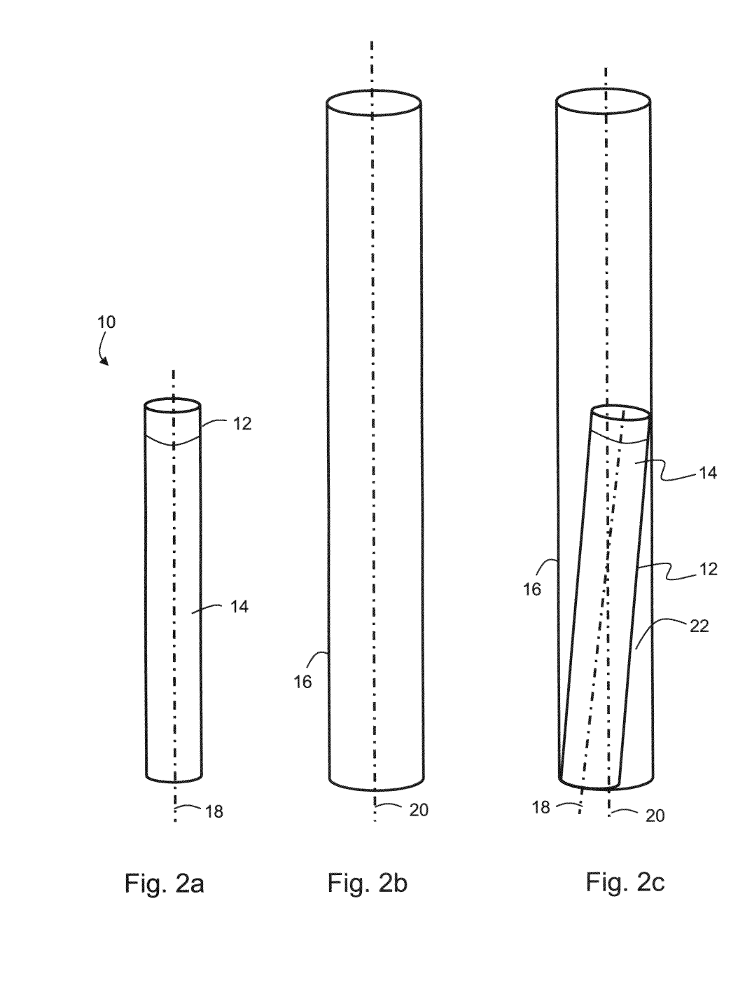

For purposes of better understanding some embodiments of the present invention, as illustrated in FIGS. 2-9 of the drawings, reference is first made to conventional NMR spectroscopy procedures as illustrated in FIGS. 1a-b.

FIG. 1a illustrates a conventional NMR spectroscopy procedure in which two reagents are mixed (1) to produce a crude mixture. A sample from the mixture is taken (2) and is being evaporated from H-solvent (3). Subsequently, a deuterated solvent is added to the sample (4), and the resulting mixture is placed (5) in an NMR sample tube for performing the analysis (6). The procedure illustrated in FIG. 1a is cumbersome and results in waste of both the reagents and the deuterated solvent.

FIG. 1b illustrates another conventional NMR spectroscopy procedure in which a special NMR tube 7 and an insert 8 are employed. The deuterated solvent is placed in the special NMR tube and the sample is placed in the insert. The insert is provided with a holder 9 for capping the insert once filled with the sample. The special NMR tube has a tapered shape so as to allow it to receive the capped insert in coaxial relationship. Once the insert is placed and aligned coaxially with the tapered tube, the tapered tube and the insert are placed in an NMR spectrometer for performing the analysis. While this technique allows not wasting the sample and the deuterated solvent, it is still complicated because the amount of deuterated solvent must be accurately measured before filling the special tube. Moreover, the special NMR tube and the insert are expensive.

While conceiving the present invention it has been hypothesized and while reducing the present invention to practice it has been realized that NMR spectroscopy can be significantly simplified while reducing the overall cost and pollution associated with material waste.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

Referring now to the drawings, FIGS. 2a-c illustrate a device 10 for NMR spectroscopy. Device 10 comprises a sealed capillary 12 having therein a lock material 14. The body of capillary 12 can be made, for example, of glass or any other material suitable for NMR spectroscopy. Preferably, the body of capillary 12 is made of a material which does not produce or produces a sufficiently weak NMR signal, so as not to interfere with the measurement. A representative example for such material is glass. Capillary 12 can be flame-sealed.

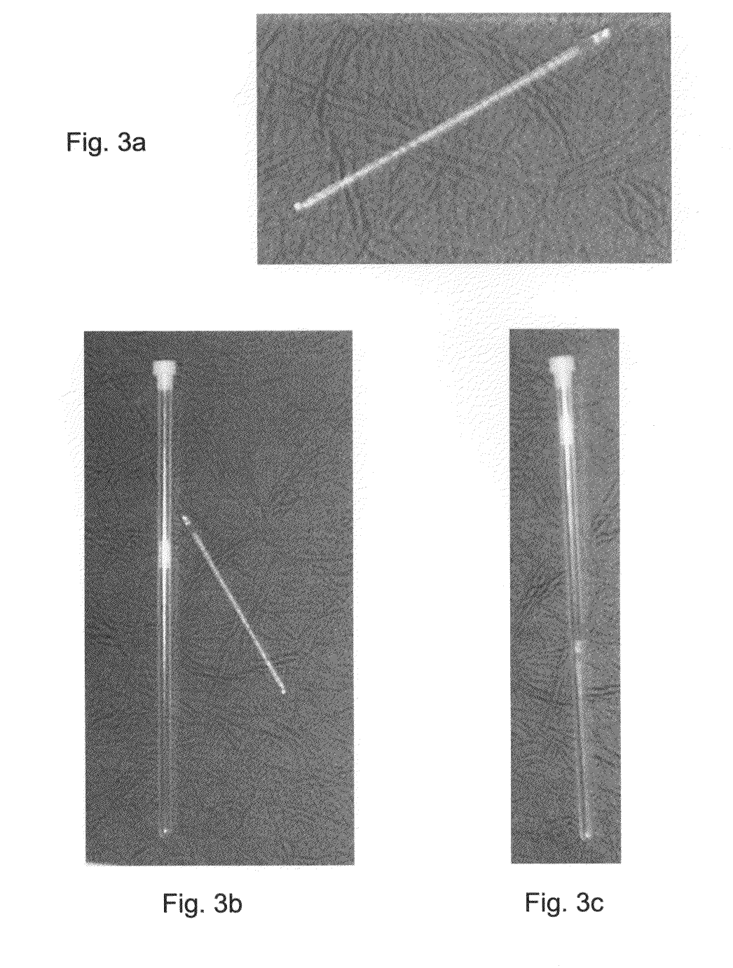

In various exemplary embodiments of the invention capillary 12 can be positioned within an NMR sample tube 16 in a non-coaxial manner. Specifically, capillary 12 can be positioned within sample tube 16 such that a longitudinal axis 18 of capillary 12 is displaced or slanted with respect to a longitudinal axis 20 of sample tube 16. FIGS. 3a-c are images showing a prototype of device 10, where FIG. 3a shows the sealed capillary, FIG. 3b shows the sealed capillary and the NMR sample tube and FIG. 3c shows the capillary once positioned in the sample tube.

Capillary 12 typically has a cylindrical shape. The outer diameter of capillary 12 is smaller that the inner diameter of sample tube 16 so as to allow positioning of the capillary within the tube. Preferably, the difference between the inner diameter of sample tube 16 and the outer diameter of capillary 12 is sufficient for allowing sample material to occupy the volume 22 between capillary 12 and tube 16. For example, the outer diameter of capillary 12 can be about half of the outer diameter of tube 16. Typically, the outer diameter of capillary 12 is smaller than 3 mm.

The advantage of allowing capillary 12 to be positioned within tube 16 such that the longitudinal axes are not-coaxial is that it substantially simplifies the use of device 10 in NMR spectroscopy analysis. Thus, unlike traditional devices in which the insert has to be accurately aligned coaxially with the outer tube, the device of the present embodiments can be simply positioned within the sample tube without performing any alignment procedure and without using alignment spacers or intricate profile inserts which complicate the procedure and increase cost.

The advantage of having capillary 12 sealed is that it does not require the user to fill the lock material prior to the NMR spectroscopy analysis. This is in contrast to traditional devices in which the user must exercise a complicated procedure whereby an accurate amount of the lock material is first placed within the outer tube and thereafter the insert with the sample is positioned within the outer tube.

Capillary 12 can contain many types of lock materials. Being completely sealed, capillary 12 prevents any chemical reaction between the lock material and the sample of interest. Thus, the use of capillary 12 allows performing an NMR spectroscopy procedure even with a lock material that would otherwise react with the sample of interest. Lock material 14 preferably comprises a deuterated solvent, such as, but not limited to, deuterobenzene (C₆D₆), deuterotoluene (C₇D₈), deuteromethanol (e.g., CH₃OD, CD₃OD), deuteroacetone ((CD₃)₂CO), acetonitryl-d (CD₃CN), tetrahydrofurane-d (e.g., THF-D₄, THF-D₈), deuterochloroform (CDCl₃), methylenechloride-d (CD₂Cl₃), deuterodimethylsulfoxide (DMSO-d₆), dimetylformamide-d (e.g., (CD₃)₂NCDO, (CD₃)₂NCHO), and deuteriumoxide (D₂O).

In various exemplary embodiments of the invention capillary 12 is reusable. Specifically, once tube 16 with capillary 12 positioned therein is subjected to an NMR spectroscopy analysis, lock material 14 remains in capillary 12 such that the same capillary (and the same lock material) can be positioned in another sample tube and be used in a subsequent NMR spectroscopy analysis. Such reuse of the lock material substantially reduces the cost of the procedure since some lock materials (e.g., C₆D₆ and C₇D₈) are known to be expensive. For example, C₆D₆ and C₇D₈ are distributed to customers at a price of thousands of U.S. dollars per 100 milliliters.

The device of the present embodiments may, if desired, be presented in a pack such as an NMR kit, which may contain one or more units of the device and one or more units of NMR sample tubes. In some embodiments the number of NMR sample tube units is larger than the number of capillary units. For example, the kit may include a single unit of device 10 and several units of sample tube 16. The kit may be accompanied by instructions for recommended NMR spectroscopy procedure. The pack or dispenser device may also be accompanied by a notice in a form prescribed by a governmental agency regulating the manufacture, use or sale of chemicals.

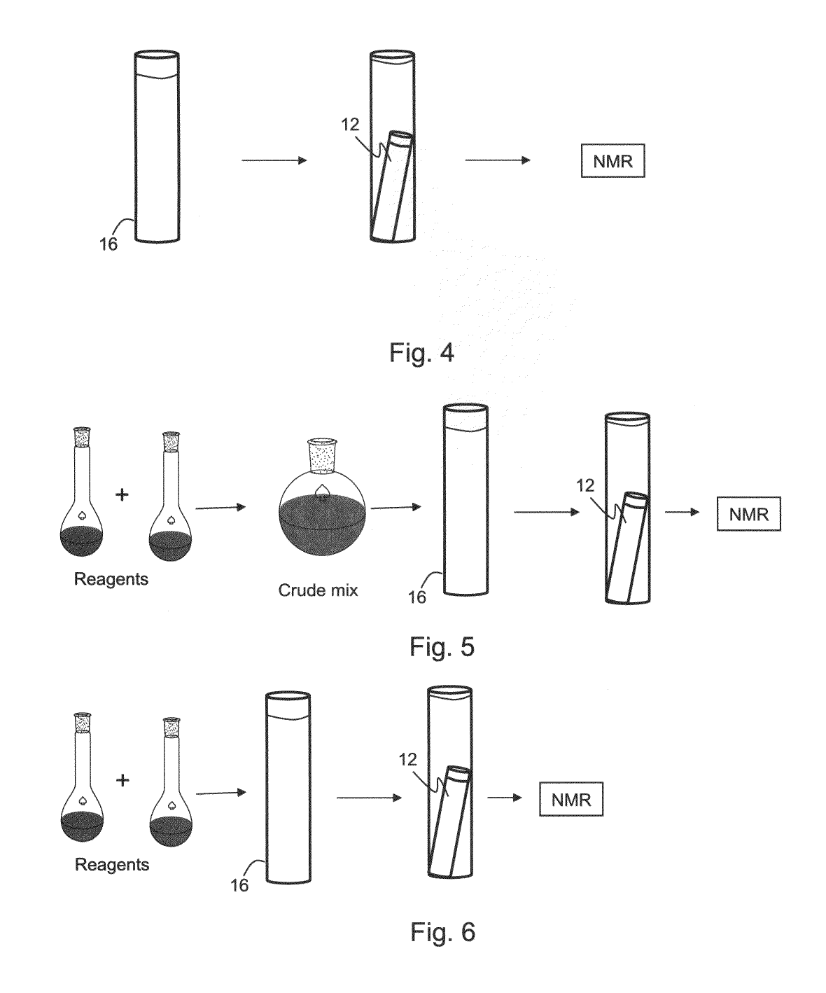

FIG. 4 illustrates a method of analyzing a non-deuterated sample, according to various exemplary embodiments of the present invention. The method can begins by placing the sample in NMR sample tube 16, and continues by placing the sealed capillary 12 in sample tube 16 in a non-coaxial manner. The method can proceed to a step in which an NMR spectroscopy is performed by placing the NMR tube 16 in an NMR spectrometer (not shown).

FIG. 5 illustrates a more detailed procedure. In this embodiment, two reagents are mixed to produce a crude mixture, as known in the art. Subsequently, a sample from the crude mixture is placed in NMR sample tube 16, and sealed capillary 12 is placed in sample tube 16 in a non-coaxial manner. NMR tube 16 and capillary 12 are then placed in an NMR spectrometer (not shown). Once the analysis is performed the sample can be returned to the crude mixture container.

An alternative embodiment is illustrated in FIG. 6. In this embodiment, the reagents are mixed into sample tube 16 without using any additional container. Subsequently, capillary 12 is placed in sample tube 16 in a non-coaxial manner, and NMR spectroscopy is performed as described above.

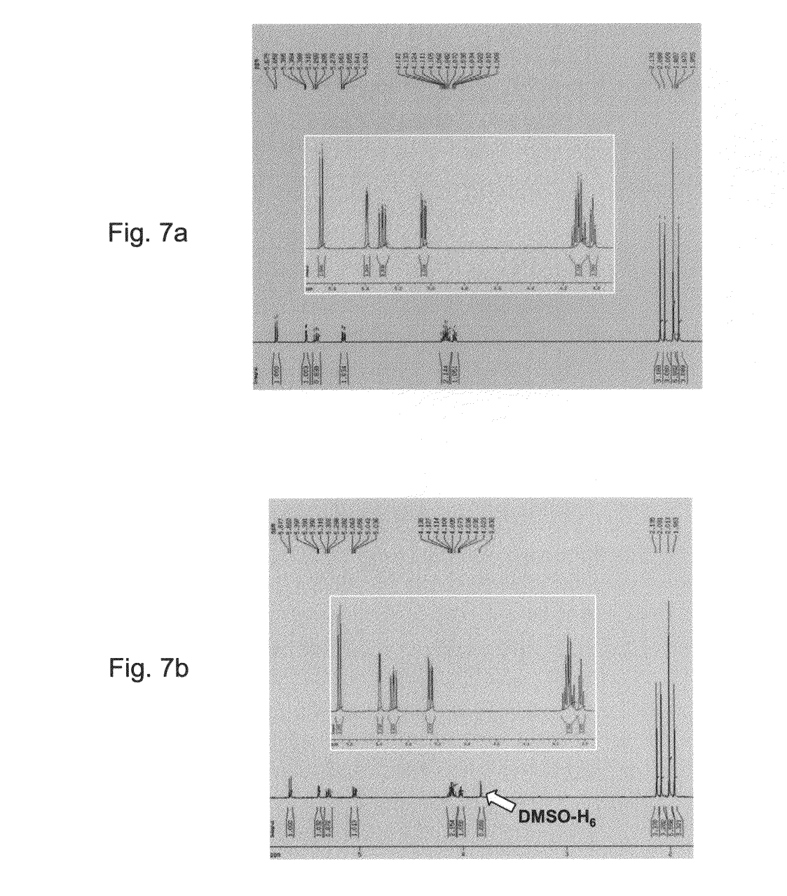

FIGS. 7a-b are ¹H NMR spectra of D-galactose peracetate in CDCl₃ as acquired using traditional technique (FIG. 7a) and D-galactose peracetate in CHCl₃ as acquired using a capillary having therein DMSO-d₆ in accordance with some embodiments of the present invention (FIG. 7b). The DMSO-H₆ signal which is present in DMSO-d₆ is marked in FIG. 7b by a block arrow. As shown in FIG. 7b the quality of measurement is high even though the DMSO-d₆ reference was external and the capillary was not coaxial with the NMR tube.

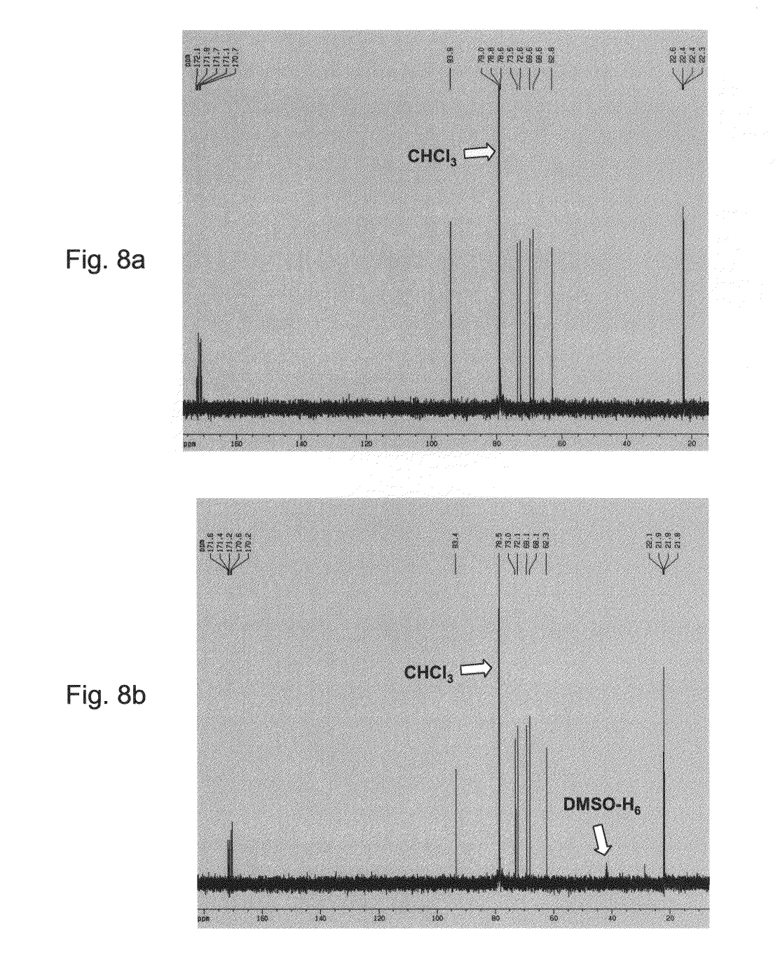

FIGS. 8c-d are ¹³C NMR spectra of D-galactose peracetate in CDCl₃ as acquired using traditional technique (FIG. 8c) and D-galactose peracetate in CHCl₃ as acquired using a capillary having therein DMSO-d₆ in accordance with some embodiments of the present invention (FIG. 8d). The DMSO-H₆ is marked in FIG. 8b and the CHCl₃ signals (present in CDCl₃) are marked in FIGS. 8a-b. As shown in FIG. 8b the quality of measurement is high.

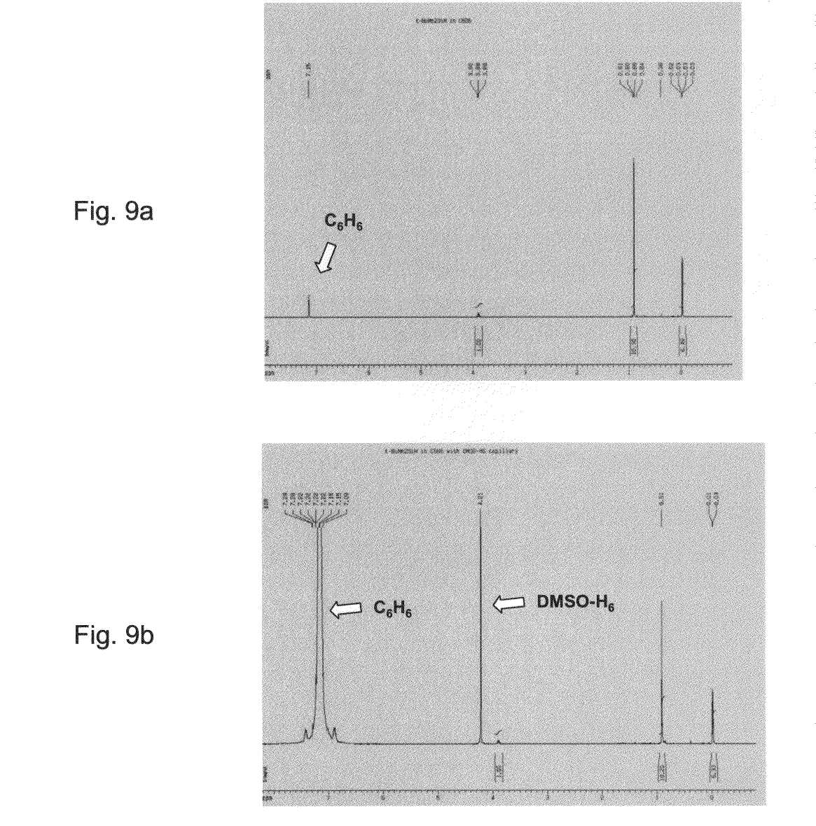

FIGS. 9a-b are ¹H NMR spectra of t-BuMe₂SiH in C₆D₆ as acquired using traditional technique (FIG. 9a) and t-BuMe₂SiH in C₆H₆ as acquired using a capillary having therein DMSO-d₆ in accordance with some embodiments of the present invention (FIG. 9b). The C₆H₆ and DMSO-H₆ signals are marked by block arrows. As shown in FIG. 9b the quality of measurement is high.

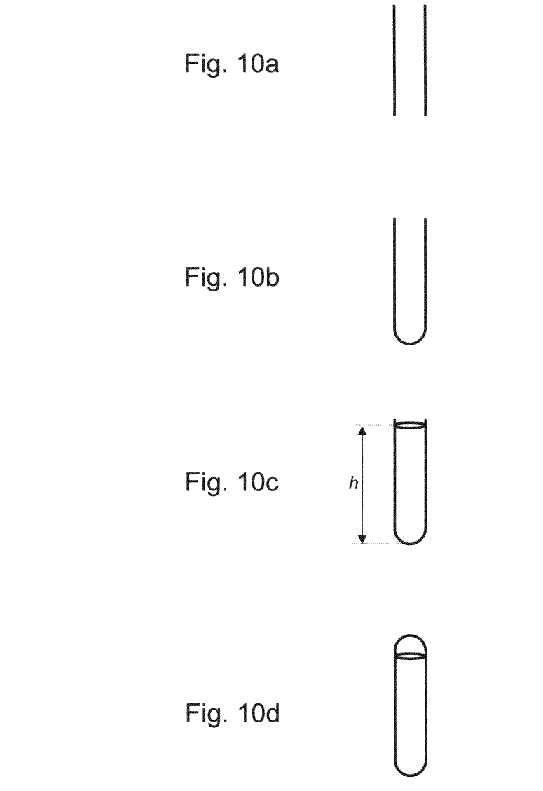

FIGS. 10a-d illustrate a method suitable for manufacturing device 10 according to some embodiments of the present invention.

The method can begin by sealing a capillary (FIG. 10a) from one side (FIG. 10b). For example, a glass Pasteur pipette or any other tubular structure suitable for positioning in an NMR tube, can be sealed by a sealing flame from one side. The capillary is preferably cylindrical having a sufficiently small outer diameter to allow its positioning within an NMR sample tube. Typically, the outer diameter of the capillary is smaller than 3 mm.

Subsequently, the capillary can be filled by a lock material (FIG. 10c). Any lock material suitable for NMR spectroscopy can be used, include, without limitation, deuterobenzene (C₆D₆), deuterotoluene (C₇D₈), deuteromethanol (e.g., CH₃OD, CD₃OD), deuteroacetone ((CD₃)₂CO), acetonitryl-d (CD₃CN), tetrahydrofurane-d (e.g., THF-D₄, THF-D₈), deuterochloroform (CDCl₃), methylenechloride-d (CD₂Cl₃), deuterodimethylsulfoxide (DMSO-d₆), dimetylformamide-d (e.g., (CD₃)₂NCDO, (CD₃)₂NCHO) and deuteriumoxide (D₂O).

Typically, less than 100 microliters of lock material are introduced into the capillary, such that the height h of the lock material in the capillary is about 2-3 centimeters. Preferably, but not obligatorily, the lock material fills the entire volume of the capillary.

Once the capillary is filled, the method proceeds by sealing the second side of the capillary (FIG. 11) while ensuring vacuum conditions in the capillary. The sealing of the second side can be done by a sealing flame or any other sealing technique. Vacuuming can be achieved using any pump known in the art. In some embodiment vacuuming is by a pump which provides a pressure of 0.1 torr or less. When the lock material is volatile at low pressure, the lock material is preferably frozen, e.g., by liquid air.

It is expected that during the life of a patent maturing from this application many relevant sample tubes for use in NMR spectroscopy will be developed and the scope of the term sample tube is intended to include all such new technologies a priori.

As used herein the term “about” refers to ±10%.

The terms “comprises”, “comprising”, “includes”, “including”, “having” and their conjugates mean “including but not limited to”.

The term “consisting of means “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise. For example, the term “a compound” or “at least one compound” may include a plurality of compounds, including mixtures thereof.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting.

What is claimed is:

1. A device for NMR spectroscopy, comprising a sealed capillary having therein a lock material and being positionable within an NMR sample tube in a non-coaxial manner.

2. The device of claim 1, wherein said capillary is flame-sealed.

3. The device of claim 1, wherein said lock material comprises a deuterated solvent.

4. The device of claim 3, wherein said deuterated solvent comprises deuterobenzene (C₆D₆).

5. The device of claim 3, wherein said deuterated solvent comprises deuterotoluene (C₇D₈).

6. The device of claim 3, wherein said deuterated solvent comprises deuteromethanol.

7. The device of claim 3, wherein said deuterated solvent comprises deuteroacetone ((CD₃)₂CO).

8. The device of claim 3, wherein said deuterated solvent comprises acetonitryl-d (CD₃CN).

9. A method of manufacturing a device for NMR spectroscopy, comprising filling a capillary with a lock material, and sealing said capillary while ensuring vacuum conditions in said capillary.

10. The method of claim 9, wherein said sealing is by a sealing flame.

11. The method of claim 9, wherein said lock material comprises a deuterated solvent.

12. The method of claim 11, wherein said deuterated solvent comprises deuterobenzene (C₆D₆).

13. The method of claim 11, wherein said deuterated solvent comprises deuterotoluene (C₇D₈).

14. The method of claim 11, wherein said deuterated solvent comprises deuteromethanol.

15. The method of claim 11, wherein said deuterated solvent comprises deuteroacetone ((CD₃)₂CO).

16. The method of claim 11, wherein said deuterated solvent comprises acetonitryl-d (CD₃CN).

17. An NMR kit, comprising:
at least one NMR sample tube; and
at least one sealed capillary having therein a lock material and being positionable within said NMR sample tube in a non-coaxial manner.

18. The kit of claim 17, wherein said lock material comprises a deuterated solvent.

19. The kit of claim 18, wherein said deuterated solvent comprises deuterodimethylsulfoxide (DMSO-d₆).

20. The kit of claim 18, wherein said deuterated solvent comprises deuterobenzene (C₆D₆).

21. The kit of claim 18, wherein said deuterated solvent comprises deuterotoluene (C₇D₈).

22. The kit of claim 18, wherein said deuterated solvent comprises deuteromethanol.

23. The kit of claim 18, wherein said deuterated solvent comprises deuteroacetone ((CD₃)₂CO).

24. The kit of claim 18, wherein said deuterated solvent comprises acetonitryl-d (CD₃CN).

25. A method of analyzing a sample, comprising:
placing the sample in an NMR sample tube;
placing a sealed capillary having therein a lock material in said NMR sample tube in a non-coaxial manner; and
performing an NMR spectroscopy.
